(19) United States
(12) Patent Application Publication
(10) Pub. No.: US 2008/0017105 A1
(43) Pub. Date: Jan. 24, 2008

(54) Substrate Processing Device

(75) Inventors: Shuji Moriya, Yamanashi (JP); Tsuneyuki Okabe, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/579,113

(22) PCT Filed: Jun. 17, 2005
(86) PCT No.: PCT/JP05/11106

§ 371 Date: Oct. 31, 2006

(30) Foreign Application Priority Data
Jun. 22, 2004 (JP) 2004-183238

(51) Int. Cl. B01J 4/00; G05D 7/06; H01L 21/205; H01L 21/3065

(52) U.S. Cl. 118/708

(57) ABSTRACT

Branch piping (18) branches off from the upstream side of opening/closing valves (13d, 14d) provided near the entrance of a processing chamber (11) of a gas supply system for supplying a processing gas, and the branch piping (18) is connected to gas discharge piping (17). In the branch piping (18) are provided a gas flow rate detection mechanism (19) and opening/closing valves (13h, 14h) for switching a flow path between the processing chamber (11) side and the branch piping (18) side. The gas flow rate detection mechanism (19) causes a gas to flow through a resistance body to measure a pressure across the resistance body, detecting a gas flow rate from the pressure difference. Mass flow controllers (13a, 14a) are tested or corrected by the detected value.

### FIELD OF THE INVENTION

The present invention relates to a substrate processing device for processing a substrate such as a semiconductor wafer, a glass substrate for a liquid crystal display (LCD) and the like by using a processing gas.

### BACKGROUND OF THE INVENTION

Conventionally, there has been widely used, in a manufacturing process of a semiconductor device, an LCD or the like, a substrate processing device for performing an etching process or a film forming process by using a predetermined processing gas on, e.g., a semiconductor wafer and a glass substrate for the LCD.

As exemplarily shown in FIG. 6, such a substrate processing device is configured to perform a processing by respectively supplying a specific processing gas, a purge gas and the like at predetermined flow rates into a processing chamber 1 accommodating therein a substrate to be processed. Accordingly, a gas flow rate controller such as mass flow controllers (MFCs) 2a, 3a and 4a is provided at a gas supply system for supplying the purge gas and the processing gas from a purge gas supply source 2 and processing gas supply sources 3 and 4 to the processing chamber 1, respectively.

The processing chamber 1 is connected to a vacuum exhaust pump 5 through a gas exhaust line 7 in which a pressure control valve 6 is provided. The MFCs 2a, 3a and 4a of the gas supply system have opening/closing valves 2b, 3b and 4b at entrance sides thereof and filters 2c, 3c and 4c at exit sides thereof. Further, opening/closing valves 2d, 3d and 4d are provided near an entrance of the processing chamber 1. Although three gas supply systems are illustrated in FIG. 6, there are actually provided a larger number of gas supply systems (e.g., twelve or more gas supply systems in an etching processing apparatus).

In the above-described substrate processing device, a supply amount of the processing gas and the like greatly affects the processing result. Therefore, in order to perform a desired processing with high reproducibility, the, gas flow rate needs to be controlled with high accuracy by the gas flow rate controller such as the MFCs 2a, 3a and 4a.

Meanwhile, the gas flow rate controller such as the MFC generally causes a drift due to aging or degradation, or tends to suffer a change of the flow rate due to foreign materials adhered to an inner side thereof as time elapses. To this end, a flow rate testing for the gas flow rate controller such as the MFC has been conventionally carried out at regular intervals.

As for a method for testing a flow rate, the following two methods have been proposed (see, e.g., Japanese Patent Laid-open Application No. 2003-168648 (pages 3 to 7, FIGS. 1 to 6)).

In a first method, mass flow meters 3f and 4f are provided in advance in purge gas lines 3e and 4e through which purge gases are supplied to MFCs 3a and 4a for supplying processing gases, as shown in FIG. 6. Next, the purge gases are made to flow at flow rates controlled by the MFCs 3a and 4a by opening opening/closing valves 3g and 4g provided in the purge gas lines 3e and 4e and closing the opening/closing valves 3b and 4b. At this time, the flow rates of the purge gases are measured by mass flow meters 3f and 4f. Then, the testing is carried out by comparing the flow rates measured by the mass flow meters 3f and 4f with set flow rates of the MFCs 3a and 4a, respectively.

Further, in a second method, a bypass line 8, for allowing a gas to bypass the processing chamber 1 and to flow through the gas exhaust line 7, is provided to branch off from an upstream side of opening/closing valves 3d and 4d of the gas supply system and, further, a pressure gauge 9 and an opening/closing valve 10 are provided in the bypass line 8 as illustrated in FIG. 6. At a time, when the MFC 3a, which is subjected to a flow rate correction, is provided, for example, a line between the MFC 3a and an exit portion of the bypass line 8 is exhausted by the vacuum exhaust pump 5 to a predetermined depressurized atmosphere while opening the opening/closing valves 3h and 10 and closing the other opening/closing valves. Next, an inner space of the bypass line 8 is sealed by closing the opening/closing valve 10 and, then, the processing gas is made to flow at a flow rate controlled by the MFC 3a by opening the opening/closing valve 3b. At this time, a relationship between a pressure increase and an elapsed time is measured by the pressure gauge 9 and, then, the same measurement is performed after the MFC 3a is used for a specific time, to test whether the MFC 3a is normal or not based on the deviation from the initial measurement. Such a method is generally referred to as a build-up method.

In the first method, a flow rate of the flowing purge gas is measured by the mass flow meter, so that the mass flow meter needs to be provided for each of the MFCs. For example, an etching processing apparatus has about twelve gas supply systems for supplying processing gases, so that the mass flow meters as many as the gas supply systems are required, thereby increasing an installation space and a manufacturing cost thereof. Moreover, since a flow rate of a purge gas (e.g., nitrogen gas) different from an actual processing gas is measured, there may occur errors in the flow rate in case the purge gas has a property different from that of the actual gas.

In the second method, a pressure change with time at a predetermined portion of a piping system such as the bypass line is measured by a pressure gauge provided at the corresponding portion and, then, a testing is carried out based on a deviation from the initial state. In this method, however, the comparative amount of the deviation from the initial state is obtained, but the actual flow rate is not obtainable, so that it is difficult to perform the correction based on the measurement result. Moreover, since the measurement result varies depending on conditions of the lines or the valves provided therein, it is substantially impossible to obtain an accurate state of the flow rate.

### SUMMARY OF THE INVENTION

It is, therefore, an object of the present invention to provide a substrate processing device capable of testing and correcting a gas flow rate more accurately compared with a conventional one and performing a processing at an accurate gas flow rate with high accuracy without increasing the installation space or the manufacturing cost thereof.

In order to achieve the object described above, a substrate processing device of claim 1 includes: a processing chamber for accommodating therein a substrate to be processed; a gas supply system for supplying a gas from a gas supply source to the processing chamber at a predetermined flow rate controlled by a gas flow rate controller to thereby perform a predetermined processing on the substrate; a branch piping branching off from a downstream side of the gas flow rate controller of the gas supply system; a valve mechanism for selectively directing the gas to flow to the processing chamber or the branch piping; and a gas flow rate detection mechanism provided in the branch piping, the gas flow rate detection mechanism having a resistance and pressure measuring units for measuring gas pressures at upstream and downstream sides of the resistance, respectively, wherein the gas whose flow rate is controlled by the gas flow rate controller is directed to flow through the gas flow rate detection mechanism by the valve mechanism, and the gas flow rate controller is tested or corrected based on a difference between the gas pressures measured by the pressure measuring units.

Further, the substrate processing device of claim 2 is provided with a plurality of the gas supply systems, and a plurality of the gas flow rate controllers are tested or corrected by the single gas flow rate detection mechanism while sequentially switching the gas supply systems.

Moreover, the substrate processing device of claim 3 includes the branch piping which branches off from a bypass line branched off from a downstream side of the gas flow rate controller of the gas supply system.

In addition, a substrate processing device of claim 4 includes: a processing chamber for accommodating therein a substrate to be processed; a gas supply system for supplying a gas from a gas supply source to the processing chamber at a predetermined flow rate controlled by a gas flow rate controller to thereby perform a predetermined processing on the substrate; and a gas flow rate detection mechanism provided at a downstream side of the gas flow rate controller of the gas supply system, the gas flow rate detection mechanism having a resistance and pressure measuring units for measuring gas pressures at upstream and downstream sides of the resistance, respectively, wherein the gas whose flow rate is controlled by the gas flow rate controller is directed to flow through the gas flow rate detection mechanism, and the gas flow rate controller is tested or corrected by a difference between the gas pressures measured by the pressure measuring units.

Furthermore, the substrate processing device of claim 5 includes the gas supply system is configured to selectively direct the gas to flow to the processing chamber through the gas flow rate detection mechanism or without passing through the gas flow rate detection mechanism.

Moreover, the substrate processing device of claim 6 includes the resistance of the gas flow rate detection mechanism which has variable resistance values.

Further, the substrate processing device of claim 7 includes the gas flow rate detection mechanism which has a plurality of resistances of different resistance values, and the resistances are selectively used.

Additionally, the substrate processing device of claim 8 includes the gas flow rate controller which is inputted with a signal in accordance with a difference between a set flow rate and a flow rate obtained from the difference between the gas pressures measured by the pressure measuring units of the gas flow rate detection mechanism, and the corresponding gas flow rate controller is corrected.

### BRIEF DESCRIPTION OF THE DRAWINGS

FIG. 1 shows a configuration of a substrate processing device in accordance with a preferred embodiment of the present invention;

FIG. 2 illustrates a configuration of principal parts of the substrate processing device shown in FIG. 1;

FIG. 3 provides a configuration of a substrate processing device in accordance with another preferred embodiment of the present invention;

FIG. 4 presents a configuration of a substrate processing device in accordance with still another preferred embodiment of the present invention;

FIG. 5 represents a configuration of a substrate processing device in accordance with still another preferred embodiment of the present invention; and

FIG. 6 depicts a configuration of a conventional substrate processing device.

### DETAILED DESCRIPTION OF THE PREFERRED EMBODIMENT

Hereinafter, preferred embodiments of the present invention will be described in detail with reference to the accompanying drawings.

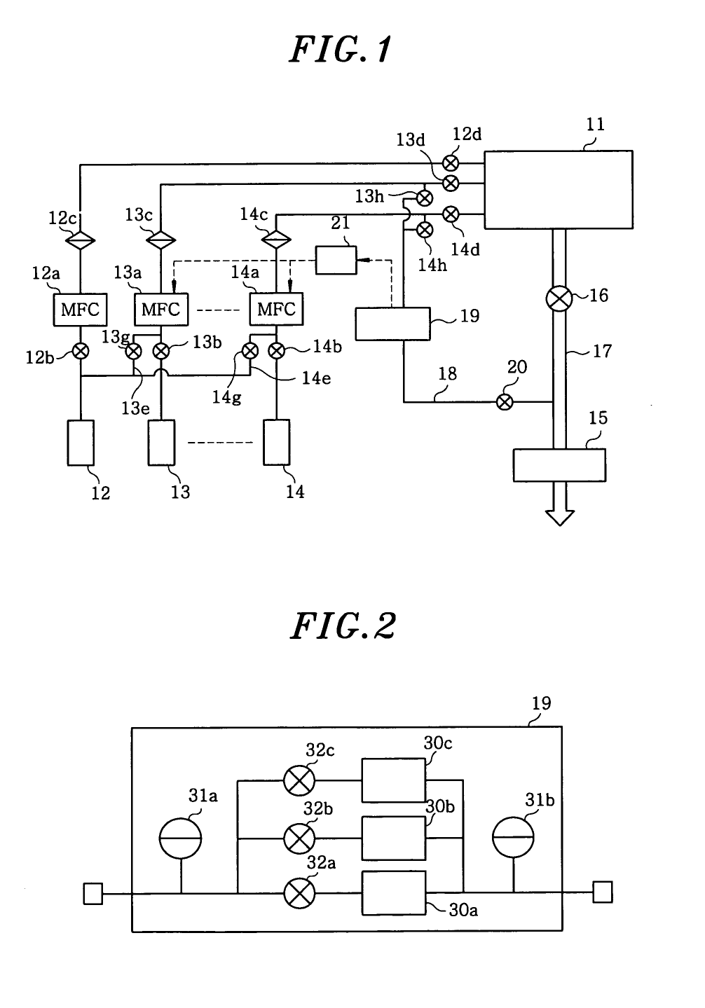

FIG. 1 shows a configuration of a substrate processing device in accordance with a first preferred embodiment of the present invention. Reference numeral 11 in FIG. 1 indicates a processing chamber accommodating therein a substrate to be processed, for performing a predetermined processing, e.g., an etching processing, a film forming processing or the like.

The processing chamber 11 is connected with gas supply systems for supplying a purge gas (e.g., nitrogen gas) and specific processing gases from a purge gas supply source 12 and processing gas supply sources 13 and 14, respectively. Although FIG. 1 illustrates three gas supply systems including the purge gas supply source 12, and the processing gas supply sources 13 and 14, there are actually provided a larger number of gas supply systems (e.g., twelve or more gas supply systems). Further, the processing chamber 11 is connected to a gas exhaust piping 17 which is in turn connected with a vacuum exhaust pump 15 and a pressure control valve 16 being provided in the gas exhaust piping 17.

The gas supply systems for supplying gases from the purge gas supply source 12 and the processing gas supply sources 13 and 14 are provided with MFCs 12a, 13a and 14a as a gas flow rate controller, respectively. The MFCs 12a, 13a and 14a respectively have opening/closing valves 12b, 13b and 14b at entrance sides thereof and filters 12c, 13c and 14c at exit sides thereof. Further, opening/closing valves 12d, 13d and 14d are provided near an entrance of the processing chamber 11.

The MFCs 13a and 14a for supplying the processing gases respectively have purge gas lines 13e and 14e through which the purge gas from the purge gas supply source 12 is supplied thereto. Furthermore, opening/closing valves 13g and 14g are respectively provided in the purge gas lines 13e and 14e.

Furthermore, a branch piping 18 branches off from respective positions between downstream sides of the MFCs 13a and 14a of the gas supply systems for supplying the processing gases and upstream sides of the opening/closing valves 13d and 14d which are provided near the entrance of the processing chamber 11, and the branch piping 18 is connected to the gas exhaust piping 17. Provided in the branch piping 18 are a gas flow rate detection mechanism 19 and opening/closing valves 13h and 14h for selectively directing the gas to flow to the processing chamber 11 or the branch piping 18. In addition, an opening/closing valve 20 is provided in a connection part of the branch piping 18 to the gas exhaust piping 17.

As illustrated in FIG. 2, the gas flow rate detection mechanism 19 includes a plurality of resistances 30a to 30c (e.g., three resistances in FIG. 2) arranged in parallel, two pressure detectors 31a and 31b provided at upstream and downstream sides of the resistances 30a to 30c, and opening/closing valves 32a to 32c for selecting any one of the resistances 30a to 30c. The resistances 30a to 30c are configured to accommodate therein, e.g., a sintered body, an orifice or a narrow tube which acts to restrict the gas flow therethrough, and the resistances 30a to 30c have a different resistance values from each other. Further, among the resistances 30a to 30c, a suitable one is selected by opening or closing the opening/closing valves 32a to 32c depending on a gas flow rate to be detected.

Specifically, when the gas flow rate to be detected is small, a resistance (e.g., 30c) having a great resistance value is selected. When the flow rate is great, a resistance (e.g., 30a) having a small resistance value is selected. When the flow rate is in-between, a resistance (e.g., 30b) having an intermediate resistance value is selected. With such a configuration, the flow rate can be accurately detected over a wide flow rate range. Accordingly, even when flow rates of the processing gases flowing through the MFCs during the actual processing (etching processing or the like) are different from each other, an accurate result can be obtained as the flow rate of the processing gases flowing through each of the MFCs during the actual processing or that adjacent thereto.

When the flow rates of the processing gases flowing through the MFCs during the actual processing are not greatly different from each other, a single resistance may be provided. Although the plural resistances are selectively used in the embodiment of FIG. 2, it is also possible to use a single resistance having variable resistance values.

In the gas flow rate detection mechanism 19 configured as described above, among the resistances 30a to 30c, a suitable one for a gas flow rate to be detected is selected in advance, and the gas is made to flow through the gas flow rate detection mechanism 19. At this time, gas pressures are respectively measured by the pressure detectors 31a and 31b to obtain a flow rate from the pressure difference therebetween.

Before the gas flow rate detection mechanism 19 is provided to the branch piping 18, a relationship between the flow rate and the pressure difference is obtained by using a MFC which is subjected to a gas flow rate correction. In this case, it is preferable to use a processing gas that is actually used and to obtain the relationship between the flow rate and the pressure difference within a flow rate range including the flow rate to be actually detected. Data of the relationship between the flow rate and the pressure difference is stored in the controller 21 or the like, for example. Consequently, an accurate flow rate can be detected from the difference in the pressures measured after the gas flow rate detection mechanism 19 is provided to the branch piping 18.

In the substrate processing device of this embodiment which is configured as described above, a substrate to be processed is accommodated in the processing chamber 11 and, further, a purge gas and specific processing gases are respectively supplied from the purge gas supply source 12 and the processing gas supply sources 13 and 14 into the processing chamber 11 at predetermined flow rates and at specific timings while exhausting the inside of the processing chamber 11 to a predetermined pressure through the gas exhaust piping 17 by the vacuum exhaust pump 15. Next, a plasma of the specific processing gases is generated in the processing chamber 11 by, e.g., a plasma generation mechanism (not shown) provided in the processing chamber 11. Then, a predetermined processing, e.g., an etching processing or the like, is performed on the substrate.

While the processing of the substrate is repetitively performed in this manner, the MFCs 13a and 14a may cause a drift due to aging or degradation, or the gas flow rate thereof be changed due to foreign substances attached to inner sides thereof as time elapses. To this end, after the MFCs have been used for a specific time, or when the number of processed substrates reaches a predetermined level, the MFCs 13a and 14a are tested or corrected. However, as for the MFC 12a for the purge gas, no accurate flow rate control is required and, e.g., nitrogen gas of a stable property flows therethrough, so that the testing or the correction thereof is not needed.

Hereinafter, processes of testing and correcting the MFC 13a will be described.

When the MFC 13a is tested and corrected, the opening/closing valve 13d provided near the entrance of the processing chamber 11 is closed and, then, the gas is directed to flow to the branch piping 18 by opening the opening/closing valves 13h and 20. At this time, the opening/closing valve 14h communicating with the branch piping 18 is closed. Next, the processing gas supplied from the processing gas supply source 13 is selected as a gas to flow by opening the opening/closing valve 13b provided at the entrance side of the MFC 13a and closing the opening/closing valve 13g of the purge gas line 13e. Then, the processing gas is supplied at a predetermined flow rate controlled by the MFC 13a.

The processing gas whose flow rate is controlled by the MFC 13a flows through the gas flow rate detection mechanism 19 along the branch piping 18. In the gas flow rate detection mechanism 19, among the resistances 30a and 30b, the one suitable for detecting the gas flow rate of the MFC 13a is selected in advance as described above. When the processing gas whose flow rate is controlled by the MFC 13a flows through the resistances 30a, 30b, gas pressures at upstream and down stream sides thereof are respectively measured by the pressure detectors 31a and 31b.

Since the relationship of the difference between the gas pressures measured by the pressure detectors 31a and 31b and the flow rate has been obtained in advance and stored in the controller 21 as described above, the accurate flow rate of the processing gas can be detected based on the pressure difference. When there is no difference between the gas flow rate detected by the gas flow rate detection mechanism 19 and the set flow rate of the MFC 13a, or when the difference therebetween is within a tolerable range, the testing and correction process is completed.

On the other hand, when the difference between the gas flow rate detected by the gas flow rate detection mechanism 19 and the set flow rate of the MFC 13a exceeds the tolerable range, the MFC 13a can be corrected to reduce the difference. For example, the MFC 13a is corrected such that the actual gas flow rate measured by the gas flow rate detection mechanism 19 becomes equal to the set flow rate by varying a voltage value (0 to 5 V) of a flow rate setting input signal of the MFC 13a. Such a correction can be automatically performed by inputting a pressure detecting signal of the gas flow rate detection mechanism 19 into the controller 21 and changing the voltage value of the flow rate setting input signal of the MFC 13a with the controller 21. Further, when the voltage value of the flow rate setting input signal which is changed by the correction exceeds a specific value from an initial value, it may be determined that the MFC 13a needs to be exchanged.

As described above, since the actual flow rate of the processing gas can be detected in the substrate processing device of this embodiment, the MFC can be tested and corrected with high accuracy and, also, the processing can be precisely performed at an accurate processing gas flow rate. Moreover, a plurality of MFCs can be tested and corrected by a single gas flow rate detection mechanism without requiring mass flow meters as many as the MFCs, so that an installation space and a manufacturing cost thereof are not increased.

Although the MFC is used as the gas flow rate controller in the aforementioned embodiment, other gas flow rate controllers than the MFC can also be used. In that case, since the flow rate can be corrected by detecting the accurate actual flow rate with the gas flow rate detection mechanism, any one can be used as the gas flow rate controller as long as it has a good reproducibility.

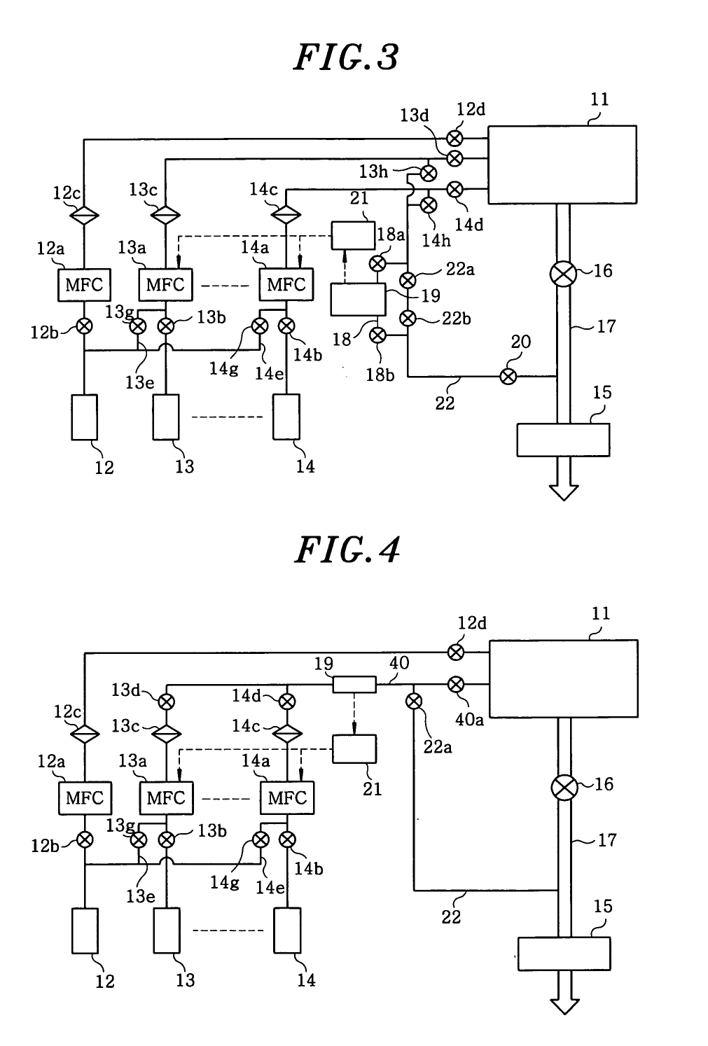

FIG. 3 provides a configuration of a substrate processing device in accordance with a second preferred embodiment of the present invention. Like reference numerals are given to the same parts as those of the substrate processing device in FIG. 1. In the substrate processing device shown in FIG. 3, a bypass line 22 branches off from respective positions between downstream sides of the MFCs 13a and 14a of the gas supply systems for supplying processing gases and upstream sides of the opening/closing valves 13d and 14d disposed near the entrance of the processing chamber 11. Further, the bypass line 22 is connected to the gas exhaust piping 17 while bypassing the processing chamber 11, and the branch piping 18 branches off from the bypass line 22. Furthermore, the bypass line 22 has the opening/closing valves 22a and 22b, and the branch piping 18 has the opening/closing valves 18a and 18b.

The gas is selectively directed to flow only through the bypass line 22 by opening the opening/closing valves 22a and 22b and closing the opening/closing valves 18a and 18b, or to flow through the gas flow rate detection mechanism 19 via the branch piping 18 by closing the opening/closing valves 22a and 22b and opening the opening/closing valves 18a and 18b.

The effects of the first embodiment can also be obtained by the second embodiment configured as described above. In the first embodiment of FIG. 1, even when the MFCs 13a and 14a are not tested and corrected, the branch piping 18 may be used as a line for exhausting the processing gas. However, in the second embodiment of FIG. 3, only when the MFCs 13a and 14a are tested and corrected, the processing gas is directed to flow through the gas flow rate detection mechanism 19. Thus, a differential pressure gauge of the gas flow rate detection mechanism 19 can be protected from by-products of the processing gas, corrosion and the like. Hence, the measurement accuracy can be stably maintained.

FIG. 4 presents a configuration of a substrate processing device in accordance with a third preferred embodiment of the present invention. Like reference numerals are given to the same parts as those of the substrate processing device shown in FIG. 1. In the substrate processing device shown in FIG. 4, lines from the MFCs 13a and 14a are configured to join at a single processing gas supply line 40 at a downstream side of the MFCs 13a and 14a of the gas supply system for supplying a processing gas and the opening/closing valves 13d and 14d and, also, the gas flow rate detection mechanism 19 is directly provided in the processing gas supply line 40. The opening/closing valves 40a and 22a are used for selectively directing the gas to flow to the processing chamber 11 or the bypass line 22. With such a configuration, the testing of the processing gas being used can be carried out while the processing is performed.

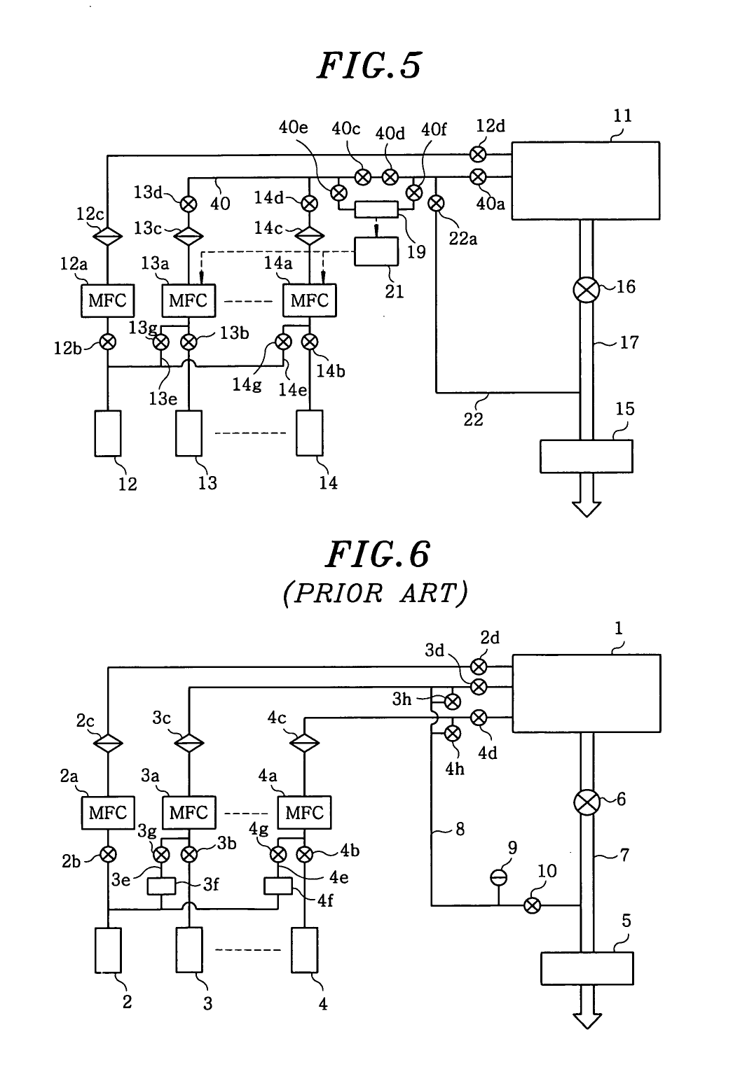

Besides, the gas flow rate detection mechanism 19 may be provided in parallel with the processing gas supply line 40 as illustrated in FIG. 5, instead of being directly provided in the processing gas supply line 4. Accordingly, by controlling opening/closing valves 40c to 40f, the gas is selectively directed to flow through the gas flow rate detection mechanism 19 or not to flow therethrough. With such a configuration, a differential pressure gauge of the gas flow rate detection mechanism 19 can be protected from by-products of the processing gas, corrosion and the like. Hence, the measurement accuracy can be stably maintained.

### INDUSTRIAL APPLICABILITY

The substrate processing device of the present invention can be used in a semiconductor device manufacturing field and the like and thus has an industrial applicability.

1-8. (canceled)

9. A substrate processing device comprising:
a processing chamber for accommodating therein a substrate to be processed;
a gas supply system for supplying a gas from a gas supply source to the processing chamber at a predetermined flow rate controlled by a gas flow rate controller to thereby perform a predetermined processing on the substrate;
a branch piping branching off from a downstream side of the gas flow rate controller of the gas supply system;
a valve mechanism for selectively directing the gas to flow to the processing chamber or the branch piping; and
a gas flow rate detection mechanism provided in the branch piping, the gas flow rate detection mechanism having a resistance and pressure measuring units for measuring gas pressures at upstream and downstream sides of the resistance, respectively,
wherein the gas whose flow rate is controlled by the gas flow rate controller is directed to flow through the gas flow rate detection mechanism by the valve mechanism, and the gas flow rate controller is tested or corrected based on a difference between the gas pressures measured by the pressure measuring units.

10. The substrate processing device of claim 9, wherein a plurality of the gas supply systems are provided, and a plurality of the gas flow rate controllers are tested or corrected by the single gas flow rate detection mechanism while sequentially switching the gas supply systems.

11. The substrate processing device of claim 9, wherein the branch piping branches off from a bypass line branched off from a downstream side of the gas flow rate controller of the gas supply system.

12. The substrate processing device of claim 10, wherein the branch piping branches off from a bypass line branched off from a downstream side of the gas flow rate controller of the gas supply system.

13. The substrate processing device of claim 9, wherein the resistance of the gas flow rate detection mechanism has variable resistance values.

14. The substrate processing device of claim 13, wherein the gas flow rate detection mechanism has a plurality of resistances of different resistance values, and the resistances are selectively used.

15. The substrate processing device of claim 9, wherein the gas flow rate controller is inputted with a signal in accordance with a difference between a set flow rate and a flow rate obtained from the difference between the gas pressures measured by the pressure measuring units of the gas flow rate detection mechanism, and the corresponding gas flow rate controller is corrected.

16. The substrate processing device of claim 13, wherein the gas flow rate controller is inputted with a signal in accordance with a difference between a set flow rate and a flow rate obtained from the difference between the gas pressures measured by the pressure measuring units of the gas flow rate detection mechanism, and the corresponding gas flow rate controller is corrected.

17. The substrate processing device of claim 14, wherein the gas flow rate controller is inputted with a signal in accordance with a difference between a set flow rate and a flow rate obtained from the difference between the gas pressures measured by the pressure measuring units of the gas flow rate detection mechanism, and the corresponding gas flow rate controller is corrected.

18. A substrate processing device comprising:
a processing chamber for accommodating therein a substrate to be processed;
a gas supply system for supplying a gas from a gas supply source to the processing chamber at a predetermined flow rate controlled by a gas flow rate controller to thereby perform a predetermined processing on the substrate; and
a gas flow rate detection mechanism provided at a downstream side of the gas flow rate controller of the gas supply system, the gas flow rate detection mechanism having a resistance and pressure measuring units for measuring gas pressures at upstream and downstream sides of the resistance, respectively,
wherein the gas whose flow rate is controlled by the gas flow rate controller is directed to flow through the gas flow rate detection mechanism, and the gas flow rate controller is tested or corrected by a difference between the gas pressures measured by the pressure measuring units.

19. The substrate processing device of claim 18, wherein the gas supply system is configured to selectively direct the gas to flow to the processing chamber through the gas flow rate detection mechanism or without passing through the gas flow rate detection mechanism.

20. The substrate processing device of claim 18, wherein the resistance of the gas flow rate detection mechanism has variable resistance values.

21. The substrate processing device of claim 20, wherein the gas flow rate detection mechanism has a plurality of resistances of different resistance values, and the resistances are selectively used.

22. The substrate processing device of claim 18, wherein the gas flow rate controller is inputted with a signal in accordance with a difference between a set flow rate and a flow rate obtained from the difference between the gas pressures measured by the pressure measuring units of the gas flow rate detection mechanism, and the corresponding gas flow rate controller is corrected.

23. The substrate processing device of claim 20, wherein the gas flow rate controller is inputted with a signal in accordance with a difference between a set flow rate and a flow rate obtained from the difference between the gas pressures measured by the pressure measuring units of the gas flow rate detection mechanism, and the corresponding gas flow rate controller is corrected.

24. The substrate processing device of claim 21, wherein the gas flow rate controller is inputted with a signal in accordance with a difference between a set flow rate and a flow rate obtained from the difference between the gas pressures measured by the pressure measuring units of the gas flow rate detection mechanism, and the corresponding gas flow rate controller is corrected.
